(19) United States
(12) Patent Application Publication
(10) Pub. No.: US 2024/0183756 A1
(43) Pub. Date: Jun. 6, 2024

(54) SYSTEM FOR REMOTE MONITORING OF WIND TURBINE

(71) Applicant: Renom Energy Services LLP, Kalhapur (IN)

(72) Inventors: S. Lakshmanan, Chennai (IN); BK Ranganath, Bengaluru (IN)

(73) Assignee: Renom Energy Services LLP, Kolhapur (IN)

(21) Appl. No.: 18/556,184

(22) PCT Filed: Apr. 28, 2022
(86) PCT No.: PCT/IN2022/050400

§ 371 Date: Oct. 19, 2023

(30) Foreign Application Priority Data
May 17, 2021 (IN) 202021055042

(51) Int. Cl. G01M 99/00; G06F 16/25; H04L 67/12

(52) U.S. Cl. CPC G01M 99/005; G06F 16/254; H04L 67/12

(57) ABSTRACT

Disclosed is a system and method for remote monitoring of wind turbines for extraction and transformation of wind turbine data into a uniform consolidated datamart, irrespective of make and model of wind turbines. The system connects a cluster of wind turbines or individual turbines to a cloud network and transmits a plurality of operating parameter data to on-premise or a remote cloud-based processing and database unit for further processing and analysis. The system operates on data acquisition from wind turbines and controls the operations of wind turbines using SCADA applications and GSM modem to provide faster data acquisition and data aggregation to give real time insights into wind turbine or wind farm performance and operational levels.

The present invention generally relates to wind driven power generation plants and more particularly relates to a system for remote monitoring of wind turbines in wind driven power generation plants to achieve maximum efficiency and power output, and method thereof.

### BACKGROUND OF THE INVENTION

Currently, the wind power generation has gained a high level of attention and acceptability. New technological developments in wind power design have contributed towards significant advances in wind energy penetration and to get optimum power from available wind. Also, the competitive tariff regime compels the wind farms to be managed more effectively in terms of utilization, predictive maintenance, process automation, decision making etc. and requiring flexibility for expansion as well.

Currently, many advanced techniques are available to monitor the wind turbines continuously and fetch and transmit the performance parameters to a remote location. In such systems, a wide range of performance parameters including input and output parameters are measured for each of a plurality of turbines. The input parameters comprise yaw angle, wind conditions, blade pitch angle and like providing information about the configuration of the wind turbine and the operating conditions in which they have mounted. The output parameters include speed of rotation, generator power, temperature values, lubricant status and vibrations of individual components, providing information on working of the turbine and its major constituent components at regular time intervals. These measured parameter data obtained from the turbine can be used for performance monitoring, condition monitoring and fault protection.

In conventional setup for supervisory control and data acquisition (SCADA) network by OEMs of wind turbines as shown in FIG. 1, the turbines are grouped into clusters (300) and then connected in serial network using network (302) based on optical Fibre/Copper wire. This setup is very capital intensive including initial investment on hardware at each wind turbines (301) and at site level, like a SCADA panel (303) including light interface units (304, 305), an ethernet switch (306), a data collection unit/OEM server (307), UPS (311). The data collection unit (307) is connected to customer center SCADA client (308) and OPC server (309) through LAN (310). Regular maintenance of the cable network connecting the turbines is also required. This setup also needs a local SCADA server to terminate the serial network and data gathering onto the local server. Projects with large number of turbines/wind farms can opt for this as a part of the initial project development. Here, the operators with small numbers of turbines are pushed to go with bigger investors to be a part of their SCADA clusters. This also increases the dependency on OEM provided SCADA data which is highly protected. Further, the existing supervisory command and data acquisition system (SCADA) provided by wind turbine equipment manufacturers are found to be very closed system having restricted access to turbine key performance data to the operators.

Accordingly, there exists need to provide a remote monitoring system for wind turbines that can overcome the drawbacks of conventional techniques.

### OBJECTS OF THE INVENTION

An object of the present invention is to monitor the operations of a wind power plant remotely.

Another object of the present invention is to acquire real time series data of wind turbines and transfer the same to a cloud based network where the data processing and storage can be made.

Still another object of the present invention is to provide an economically viable, technically robust and scalable system capable of integrating multiple makes and models of wind turbines on to one single platform making it a completely OEM agnostic system.

Still another object of the present invention is to provide faster data acquisition and data aggregation to give real time insights into wind turbine or wind farm performance and operational levels.

### SUMMARY OF THE INVENTION

Accordingly in one aspect, the present invention provides a system for remote monitoring of wind turbines. The wind turbines are either an individual unit or a cluster of plurality of wind turbines that are equipped with plurality of sensors with signal conditioning and processing circuits for capturing operational parameters related to input and output characteristics thereof. The system extracts and transforms the wind turbine data into a uniform consolidated datamart, irrespective of make and model of wind turbine. The system comprises of a GPRS modem supported with GPRS technology for data transmission, receiving wind turbine data from the plurality of sensors and operably connected to a cloud network either in a wired or wireless manner to facilitate data transfer there between. A M2M gateway unit receiving data from the modem, is connected to an application server providing a secured connectivity over GSM network for data transfer thereto. A SCADA server is connected to the application server through a centralized gateway module working on protocols selected from OPC, OPC-DA, IEC104, IEC103, IES101, IEC61850, MODBUS TCP & OPC-XML-DA and like, wherein the centralized gateway module converts the received data format into single IEC-61850 standard and passes to the SCADA server. A real time database module is operably connected to the SCADA server, wherein data from the SCADA server is transformed to a readable format to have a single view of all the data collected from the wind turbines. In an embodiment, the real time database module is an OLTP database configured as a central repository of real time data from the individual turbines. An OLAP database module is operably connected to the real time database module through an ETL module. An application module consumes data from the OLAP database module available at source independent of the data from real time database module to ensure that the users can analyse the historical data by slicing and dicing across the regions/farms/turbine makes & models without impacting on data collection from turbine.

In another aspect, the present invention provides a method for remote monitoring of wind turbines for extraction and transformation of wind turbine data into a uniform consolidated datamart irrespective of make and model of wind turbine. In first step, the method comprises of fetching wind turbine data from the plurality of sensors and facilitating data transfer to a cloud network (200) through a modem (106, 106a) either in a wired or wireless manner. In next step, the data from the modem is transferred to an application server of a cloud network through a M2M gateway unit providing a secured connectivity over GSM network for data transfer thereto. The received data is then passed to a SCADA server through a centralized gateway, after converting the format of the received data into a single IEC-61850 standard. The data from SCADA server is then transferred to a real time database module in a readable format to have a single view of all the data collected from the wind turbines, in operably connected to the SCADA server. In next step, the data from the real time database module is transformed to have a single view of all the data collected from wind turbines and loaded into an OLAP database module using an ETL module. In next step, the data from the OLAP database module available at source is consumed into an application module independent of the data from real time database module to ensure the users can analyse the historical data by slicing and dicing across the regions/farms/turbine makes & models without impacting on data collection from turbine.

### BRIEF DESCRIPTION OF THE DRAWINGS

The objects and advantages of the present invention will become apparent when the disclosure is read in conjunction with the following figures, wherein

FIG. 1 shows a schematic representation of a remote monitoring system for wind turbines in accordance with prior art, and

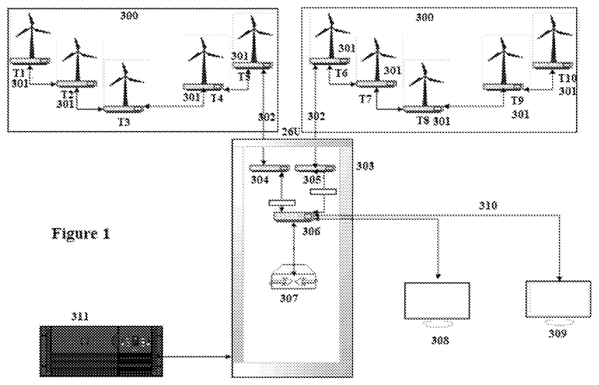

FIG. 2 shows a block representation of a system for monitoring wind turbine in accordance with the present invention, and

FIG. 3 shows a schematic representation of data flow in a system for monitoring wind turbine in accordance with the present invention.

### DETAILED DESCRIPTION OF THE EMBODIMENTS

The foregoing objects of the present invention are accomplished and the problems and shortcomings associated with the prior art, techniques and approaches are overcome by the present invention as described below in the preferred embodiments.

The present invention provides a system for monitoring wind turbines based on supervisory control and data acquisition (SCADA) techniques. The system operates on data acquisition from wind turbines and control the operations of wind turbines using SCADA applications and GSM modems. The system connects a cluster of wind turbines or individual turbines to a cloud network and transmits a plurality of operating parameter data to on-premise or a remote cloud-based processing and database unit for further processing and analysis.

The present invention is illustrated with reference to the accompanying drawings, throughout which reference numbers indicate corresponding parts in the various figures. These reference numbers are shown in bracket in the following description and in the table below.

TABLE

| Ref No | Component |
|---|---|
| 101 | Controller |
| 102 | Wind turbine |
| 103 | Wind turbine cluster |
| 104 | Serial converter unit |
| 105 | Data collection unit |
| 106 | First Modem |
| 106a | Second modem |
| 107 | Network security module |
| 108 | M2M gateway module |
| 109 | Custom gateway module |
| 110 | First server/Application server |
| 111 | Centralized gateway module |
| 112 | Second server/SCADA server |
| 113 | Real time database |
| 200 | Cloud network |
| 207 | Scada module |
| 208 | ETL module |
| 209 | OLAP database |
| 210 | Application module |
| 211, 212 | Network security modules |

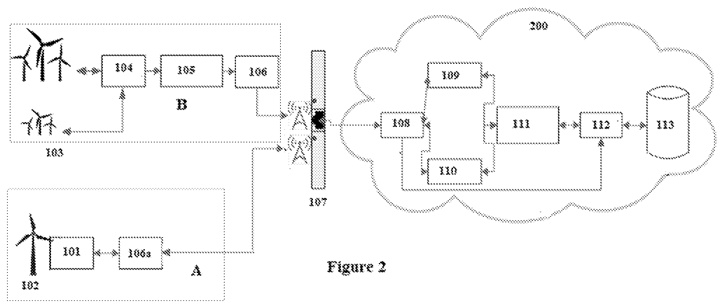

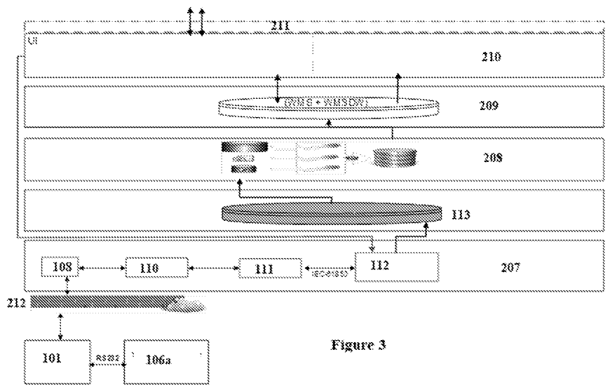

Referring to the FIGS. 2 and 3 a system (100) and method (300) for remote monitoring of wind turbine (referred as ‘the system (100)’ and ‘the method (300) hereinafter) is shown, in accordance with the present invention. The system (100) enables extraction and transformation of wind turbine data into a uniform consolidated datamart irrespective of make and model of wind turbines using an inline ETL process. It is understood here that the wind turbine can be an individual unit (102) or a cluster (103) of plurality of wind turbines. Each wind turbine is equipped with a plurality of sensors with signal conditioning and processing circuits for capturing operational parameters related to input and output characteristics of the wind turbines. The system (100) is capable of acquiring more than 50-60 Key Performance indicators from each make and model of turbines. The data acquired includes, speeds, temperatures, directions, power, voltages, current, pitching & yawing parameters, operating hours etc. The system (100) comprises a modem (106, 106a), a M2M gateway unit (108), a SCADA server (112), an ETL module (208), an OLAP database module (209) and an application module (210)

The first modem (106) is operably connected to the plurality of sensors of the cluster (103) of wind turbines to receive the wind turbine data therefrom and operably connected to a cloud network (200) either in a wired or wireless manner to facilitate data transfer there between. Similarly, the second modem (106a) is operably connected to the plurality of sensors of the individual wind turbines (102) to receive the wind turbine data therefrom and operably connected to a cloud network (200) either in a wired or wireless manner to facilitate data transfer there between. In an embodiment, the first modem (106) and the second modem (106a) are GPRS modems supported with GPRS technology for data transmission. In an embodiment, the plurality of sensors of the wind turbine cluster (103) is connected to the first modem (106) through a serial converter unit (104) and a data collection unit (105); while the plurality of sensors of the individual wind turbine (102) is connected to the second modem (106a) through a wedge controller (101). The serial converter (104) is a combination of plurality of sensors equipped with a plurality of signal conditioning and processing circuits to convert FO to Serial communication which is used more in cluster based Windfarms implementation. The plurality of sensors capture operational parameters related to input and output characteristics of the wind turbines and are transferred to the data collection unit (105) after a series of signal processing stages.

The M2M gateway unit (108) forms a front end of the cloud network (200). The M2M gateway unit (108) is connected to the modems (106/106a) and further connected to an application server (110), the SCADA server (112) and the real time database module (113) providing a secured connectivity over GSM network for data transfer. The data fetched by the sensors is thus transmitted through a network interface for further analysis and storing. The application server (110), the SCADA server (112) and the real time database module (113) allow data aggregation and archiving of the data for further detailed analytics at individual turbines or a consolidated wind farm. The real time database module (113) is an OLTP database that is focused on transaction-oriented tasks and configured as a central repository of real time data from the individual turbines which is used for further aggregation at different interval of time for consolidation, predictive analytics, regulatory purposes and future forecasting of power generation levels. The data stored in the real time database module (113) allows the operator to have a single view of all the data collected from the turbines.

The application server (110) is connected to the SCADA server (112) through a centralized gateway module (111). In an embodiment, the SCADA server (112) also receives the data directly from the modems (106, 106a) through the M2M gateway module (108), a custom gateway module (109) and the centralized gateway module (111). The centralized gateway module (111) is capable of managing multiple protocols used to connect with SCADA server (112) and convert the real time data into a readable format. In an embodiment, the centralized gateway module (111) works on protocols selected from OPC, OPC-DA, IEC104, IEC103, IES101, IEC61850, MODBUS TCP & OPC-XML-DA and like and converts the received data format into single IEC-61850 standard and passes it to the SCADA server (112).

The OLAP database module (209) is operably connected to the real time database module (113) through an ETL module (208). The ETL module (208) converts the data from multiple OEM Wind Turbines into a standard name and format of each key performance indicators. The ETL module (208) handles aggregation of real time data in to multiple Timeline averages at multiple granularity (10 mins, hourly, daily) and also manages event data to help next level computation of matrices for health indices, MTTR/BF etc. The ETL module (208) uses ETL tools selected from SQL, SSIS and like for converting real time data from different makes of turbine into a single uniform data format. This enables the user interface (UI) and the application module (210) to have a single format data as source, such that application development is independent from the database used.

The application module (210) consumes data from the OLAP database module (209) available at source independent of the data from real time database module (113). In other words, the OLAP database module/DataMart (209) is decoupled from the real time database module (113) to ensure the users can analyse the historical data by slicing and dicing across the regions/farms/turbine makes & models without impacting on data collection from turbine.

A plurality of network security modules (107, 211, 212) are configured to manage the security need of the asset connectivity with cloud & also UI Application being used by end users through internet. The plurality of network security modules (107, 211, 212) are Firewall features within the Modem/Cloud.

In another aspect, the present invention provides the method (200) for remote monitoring of wind turbines, for extraction and transformation of wind turbine data into a uniform consolidated datamart irrespective of make and model of wind turbine. The wind turbines are either an individual unit (102) or a cluster (103) of plurality of wind turbines, and are equipped with a plurality of sensors with signal conditioning and processing circuits capturing operational parameters related to input and output characteristics thereof.

The method (200) comprises the steps of:
fetching the wind turbine data from the plurality of sensors and facilitating data transfer to a cloud network (200) through a modem (106, 106a) either in a wired or wireless manner.
transferring the data from the modem (106, 106a) to an application server (110) of a cloud network (200) through a M2M gateway unit (108) providing a secured connectivity over GSM network for data transfer thereto;
converting the received data format into a single IEC-61850 standard and passing to a SCADA server (112) through a centralized gateway (111);
transferring the data from SCADA server (112) to a real time database module (113) in a readable format to have a single view of all the data collected from the wind turbines, in operably connected to the SCADA server (112);
transforming data from the real time database module (113) to have a single view of all the data collected from wind turbines and loading into an OLAP database module (209) using an ETL module (208); and
consuming data from the OLAP database module (209) available at source, into an application module (210), independent of the data from real time database module (113) to ensure the users can analyse the historical data by slicing and dicing across the regions/farms/turbine makes & models without impacting on data collection from turbine.

The process of extraction and transformation of data from each individual turbine irrespective of turbine make and model into one uniform consolidated data mart; and the speed of data acquisition and data aggregation to give real time insights into wind turbine or wind farm performance and operation levels, makes the system (100) unique. The system (100) works on any kind of GSM based network. Frequency of data acquisition can be managed from 5 sec to 20 sec based on the network strength. 4G/5G networks can go with high frequency data acquisition and 2G at 20 sec to optimize the latency b/n data packets.

Apart from the real time monitoring application, supervisory commands can be sent back to the wind turbine for START/STOP/RESET operations through a SCADA layer in case of faults or extreme conditions with authentication.

Thus the system architecture allows data acquisition from wind turbines and integrate them between different technology layers to provide real time information for an operation team and also other persons interested to make informed decisions about wind turbine functionality, performance trends, and conduct fault and break down analysis. Thus, combination of SCADA architecture and data collection from the wind turbines within a wind farm connected to the cloud server enables real time monitoring and controlling of the turbines locally or remotely. This also provides visualization of wind farm status, fault logging, alarming and provision for operator to acknowledge and raise break down maintenance orders.

In a specific embodiment, the system (100) is capable of acquiring an average of more than 50 to 60 key performance indicators from each make and model of turbines. The data acquired includes, speeds, temperatures, directions, power, voltages, current, pitching and yawing parameters, operating hours etc. These data can be of instant or cumulative values.

### Advantages of the Invention

The system (100) is economically viable, technically robust and scalable.
The SCADA based data acquisition enables real time collection of key performance indicator from a plurality of sensors within wind turbines both remotely and locally, controlling of devices, and facilitating consolidation of data at individual turbines and at wind farm levels to achieve effective monitoring and control of wind farm operations.
The new innovative way of connecting to turbines and setting up of the data acquisition unit facilitates the system (100) being easy to setup and operate.
The flexibility in the data acquisition and consolidation for regulatory requirements and operational performance analytics makes the system suitable for the investors and the service providers.
The system (100) is capable of monitoring the wind turbines irrespective of their make and model.
The system (100) provides remote monitoring and allows diagnosis of the wind turbines and helps the operator or technicians to effectively utilize the available resources and manage power generation at optimal levels.
The system (100) is capable of integrating multiple makes and models of wind turbines on to one single platform making it a completely OEM agnostic system and unique.
The system (100) provides faster data acquisition and data aggregation to give real time insights into wind turbine or wind farm performance and operational levels.

The foregoing descriptions of specific embodiments of the present invention have been presented for purposes of illustration and description. They are not intended to be exhaustive or to limit the present invention to the precise forms disclosed, and obviously many modifications and variations are possible in light of the above teaching. The embodiments were chosen and described in order to best explain the principles of the present invention and its practical application, to thereby enable others skilled in the art to best utilize the present invention and various embodiments with various modifications as are suited to the particular use contemplated. It is understood that various omission and substitutions of equivalents are contemplated as circumstance may suggest or render expedient, but such are intended to cover the application or implementation without departing from the scope of the present invention.

1. A system for remote monitoring of wind turbines for extraction and transformation of wind turbine data into a uniform consolidated datamart, irrespective of make and model of wind turbine, the wind turbines being either an individual unit or a cluster of plurality of wind turbines and equipped with plurality of sensors with signal conditioning and processing circuits capturing operational parameters related to input and output characteristics thereof, the system comprising:
a modem receiving wind turbine data from the plurality of sensors and operably connected to a cloud network either in a wired or wireless manner to facilitate data transfer there between;
a M2M gateway unit receiving data from the modem and connected to an application server providing a secured connectivity over GSM network for data transfer thereto;
a SCADA server connected to the application server through a centralized gateway, wherein the centralized gateway converts the received data format into single IEC standard and passes to the SCADA server;
a real time database module operably connected to the SCADA server wherein the data from SCADA server is transformed to a readable format to have a single view of all the data collected from the wind turbines;
an OLAP database module operably connected to the real time database module through an ETL module;
an application module consuming data from the OLAP database module available at source independent of the data from real time database module to ensure the users can analyse the historical data by slicing and dicing across the regions/farms/turbine makes & models without impacting on data collection from turbine.

2. The system as claimed in claim 1, wherein the modem is a GPRS modem supported with GPRS technology for data transmission.

3. The system as claimed in claim 1, wherein the plurality of sensors of the wind turbine cluster is connected to the modem through a serial converter unit and a data collection unit.

4. The system as claimed in claim 1, wherein the plurality of sensors of the individual wind turbine is connected to the modem through a wedge controller.

5. The system as claimed in claim 1, wherein the SCADA server receives data directly from the modems through the M2M gateway module, a custom gateway module and the centralized gateway module.

6. The system as claimed in claim 1, wherein the real time database module is an OLTP database configured as a central repository of real time data from the individual turbines.

7. The system as claimed in claim 1, wherein the centralized gateway module works on protocols selected from OPC, OPC-DA, IEC104, IEC103, IES101, IEC61850, MODBUS TCP & OPC-XML-DA and like.

8. A method for remote monitoring of wind turbines for extraction and transformation of wind turbine data into a uniform consolidated datamart irrespective of make and model of wind turbine, the wind turbines being either an individual unit or a cluster of plurality of wind turbines, and equipped with plurality of sensors with signal conditioning and processing circuits capturing operational parameters related to input and output characteristics thereof, the method comprising:
fetching wind turbine data from the plurality of sensors and facilitating data transfer to a cloud network through a modem either in a wired or wireless manner;
transferring the data from the modem to an application server of a cloud network through a M2M gateway unit providing a secured connectivity over GSM network for data transfer thereto;
converting the received data format into a single IEC standard and passing to a SCADA server through a centralized gateway;
transferring the data from SCADA server to a real time database module in a readable format to have a single view of all the data collected from the wind turbines;
transforming data from the real time database module to have a single view of all the data collected from wind turbines and loading into an OLAP database module using an ETL module; and
consuming data from the OLAP database module available at source, into an application module, independent of the data from real time database module to ensure the users can analyse the historical data by slicing and dicing across the regions/farms/turbine makes & models without impacting on data collection from turbine.

9. The method as claimed in claim 8, wherein the modem is a GPRS modem supported with GPRS technology for data transmission.

10. The method as claimed in claim 8, wherein the plurality of sensors of the wind turbine cluster is connected to the modem through a serial converter unit and a data collection unit.

11. The method as claimed in claim 8, wherein the plurality of sensors of the individual wind turbine is connected to the modem through a wedge controller.

12. The method as claimed in claim 8, wherein the SCADA server receives the data directly from the modem through the gateway modules.

13. The system as claimed in claim 8, wherein the real time database module is a OLTP database configured as a central repository of real time data from the individual turbines.

14. The method as claimed in claim 8, wherein the centralized gateway works on protocols selected from OPC, OPC-DA, IEC104, IEC103, IES101, IEC61850, MODBUS TCP & OPC-XML-DA and like.
